(19) United States
(12) Patent Application Publication
(10) Pub. No.: US 2025/0343542 A1
(43) Pub. Date: Nov. 6, 2025

(54) DEVICE FOR CONTROLLING, PROTECTING AND MONITORING THE STATE OF HEALTH OF A POWER TRANSISTOR

(71) Applicants: SAFRAN, PARIS (FR); CENTRE NATIONAL DE LA RECHERCHE SCIENTIFIQUE, PARIS CEDEX 16 (FR); INSTITUT NATIONAL POLYTECHNIQUE DE TOULOUSE, TOULOUSE CEDEX 4 (FR); UNIVERSITE PAUL SABATIER - TOULOUSE II, TOULOUSE CEDEX 9 (FR)

(72) Inventors: Stéphane Joseph AZZOPARDI, Moissy-Cramayel (FR); Thanh Long LE, Moissy-Cramayel (FR); Frédéric RICHARDEAU, Toulouse Cedex 7 (FR); Wadia JOUHA, Toulouse Cedex 7 (FR); Yazan BARAZI, Toulouse Cedex 7 (FR); Nicolas ROUGER, Toulouse Cedex 7 (FR); Jean-Marc BLAQUIERE, Toulouse Cedex 7 (FR); Sébastien VINNAC, Toulouse Cedex 7 (FR); Mathis PICOT, Toulouse Cedex 7 (FR)

(21) Appl. No.: 18/998,693

(22) PCT Filed: Jul. 24, 2023
(86) PCT No.: PCT/FR2023/051145

§ 371 Date: Jan. 27, 2025

(30) Foreign Application Priority Data
Jul. 27, 2022 (FR) 2207714

(51) Int. Cl. H03K 17/0812; G01R 31/26; H03K 17/18

(52) U.S. Cl. CPC H03K 17/08122; G01R 31/2621; H03K 17/18; H03K 2217/0027

(57) ABSTRACT

A device for controlling and protecting a power transistor, comprising: a nominal switching circuit for the transistor, a short-circuit detection circuit which keeps the transistor in the conducting state and detects an increase or decrease in the voltage VGS of the transistor relative to reference voltages representative of a short-circuit of the transistor; a protection circuit which discharges the gate of the transistor after the detection of a short-circuit; and a circuit for measuring and controlling the nominal switching circuit, the short-circuit detection circuit and the protection circuit.

### TECHNICAL FIELD

The invention relates to the field of power electronics, and advantageously that of power electrification and electric hybridisation in the aeronautical industry where performant, integrated, reliable and safe electronic power systems are looked for.

### PRIOR ART

The introduction of wide-bandgap power semiconductor components like the MOSFET transistor made of silicon carbide (SiC) within static power converters or modules, has allowed reducing by 15 to 30% the on-board mass and the volume, and increasing by 2 to 3 points the electrical efficiency of these converters. Yet, it leads to a problem of protection and monitoring of the state-of-health of these components, which demonstrate weaknesses and instabilities that the MOSFET and IGBT transistors of the silicon technology had.

The origin of a short-circuit of a power transistor may be internal (for example due to a disturbance or a failure of a circuit for controlling the gate of one of the transistors of the converter, or due to a breakdown of one of the transistors of the converter) or external to this transistor (for example a short-circuit in the motor winding or an insulation fault from the aircraft ground when this converter is a voltage inverter on the motor). The main short-circuit typologies of a power transistor are:
a) internal fault of an arm of the converter by the simultaneous control of the two power transistors of this arm;
b) internal fault by voltage breakdown of one of the power transistors of an arm of the converter;
c) external fault creating a conduction path between two arms of the converter, for example by the motor winding controlled by the converter;
d) external fault by mass or ground return.

The configuration a) results from an internal fault by the control and it is usually designated as “Hard Switching Fault” (HSF), or by a type 1 fault. The configuration b) also results from an internal fault but this time by a breakdown of a component due to an excessive voltage or by an abrupt short-circuit just at the output of the arm. The configurations c) and d) pertain to the same family as the configuration b) but these result this time from an external fault within the load or by an insulation fault path. Although they have quite different fault time dynamics, the cases b), c) and d) are usually designated by the unique name “Fault Under Load” (FUL), or as type 2 fault.

The SiC technology is less robust and less enduring with regards to accidental electrical regimes such as a short-circuit. With such SiC-based components, the acceptable number of short-circuit cycles is often lower than 1,000 with reference to the IGBT silicon standard. In addition, the short-circuit hold duration, i.e. the duration of exposure to the short-circuit beyond which the component will have an irreversible permanent fault which will propagate within the converter with high hazardousness, is generally reduced by at least 50% in comparison with the silicon technology (IGBT Si, MOSFET Si).

This reduced short-circuit hold time is due to the characteristics of the SiC components (short channels, high cell density, high electric fields) which generate high increases in current density and thermal power density in this component type. The high thermal power density noticed on a short-circuited SiC-based power transistor is accompanied by a fast rise in its temperature to levels much higher than those known for silicon components. This results in an increase in the thermomechanical stresses in the region of the component comprising the source contact metal, the protective oxide and the gate, with a risk of progressive cracking at each accumulated cycle, then breakage of the protective oxide, as well as softening and then melting of the source contact metal layer infiltrating into the cracked protective oxide. This mechanism results in the formation of a network of conductive metal filaments, more or less stable over time, between the source contact metal and the gate of the transistor, these filaments being responsible for more or less stable gate leakage currents.

In parallel to the short-circuit problem, SiC-based power transistors also suffer from a weakness and an “electrical” instability of their gate. The reasons for this are multiple: on the one hand, the presence of a deposited gate oxide with a thickness at least three times thinner than in the silicon technology, bringing an involved electric field at least three times higher and, on the other hand, the occurrence of a considerable drift in their threshold voltage due to interface defects (structural and by the migration of contaminants) with interface states that are more or less likely to capture or re-emit carriers and evolving over time, between the gate oxide and the SiC active zone of the component.

There are several methods for monitoring and detecting the apparition of a short-circuit on power transistors: direct measurement of the drain current I DS of the power switch, measurement of the voltage V_{DS}, measurement of the dynamic grid current, measurement of the gate charge Q_{G}. Nonetheless, all of these methods have one or more of the following drawbacks: power capture by the power component, difficulties and overcost related to the integration of components for monitoring and detecting high voltages in the control circuit of the power component, excessively long response times.

### DISCLOSURE OF THE INVENTION

The present invention aims to provide a solution for controlling, monitoring and protecting a power transistor with regards to short-circuits which does not affect the nominal switching mode of the power transistor and which does not have the drawbacks of the prior art indicated hereinabove.

For this purpose, a device for controlling and protecting a power transistor is provided, comprising at least:
a nominal switching circuit of the power transistor, configured to control (by applying a nominal switching voltage on the gate of the power transistor) a nominal switching of the power transistor from a conducting state into a non- conducting state, holding of the power transistor in the non-conducting state, and a nominal switching of the power transistor from the non-conducting state into the conducting state;
a short-circuit detection circuit, configured to hold the power transistor in the conducting state (by applying a voltage for holding in the conducting state on the gate of the power transistor) and to detect an increase in the value of the voltage V_{GS} (gate-source voltage) of the power transistor above a value of a high reference voltage, or a drop in the value of the voltage V_{GS} below a value of a low reference voltage, which are representative of a short-circuit of the power transistor (of the FUL type by means of a supplied current output by the gate of the power transistor upon an increase in the voltage V_{GS} above the high reference voltage, and of the HSF type by means of a consumed current entering through the gate of the power transistor upon an increase in the voltage V_{GS} above the high reference voltage);
a protection circuit, configured to discharge the gate of the power transistor after detection of a short-circuit of the power transistor;
a measurement and control circuit configured to deliver control signals at the input of the nominal switching circuit, the short-circuit detection circuit and the protection circuit such that:
in the absence of a detected short-circuit, an input of the protection circuit coupled to the gate of the power transistor is set in a high-impedance state;
in the presence of a detected short-circuit, outputs of the nominal switching circuit and the short-circuit detection circuit coupled to the gate of the power transistor are each set in a high-impedance state.

The invention provides a novel electronic architecture of a transistor gate control or driver circuit, commonly so-called “gate-driver”, comprising several output channels each capable of operating in a modular and selective manner to carry out a dedicated function. Each output branch of the device is dedicated to one single function that could be carried out independently and optimised, on demand, without exclusion with regards to the other functions of the device.

In the control and protection device according to the invention, the different circuits used to control and protect the power transistor, i.e. to carry out the switching of the power transistor, hold it in a conducting or non-conducting state, and monitor the electrical behaviour of the power transistor, are coupled to the gate of the power transistor parallel to each other through different resistors which values, also different from each other, are adapted to the function (slow switching, fast switching, voltage measurement, etc.) carried out on the power transistor by each of these circuits.

This control and protection device is based on an architecture of electronic circuits operating at low voltage which could be integrated with a very high density in an ASIC-type integrated circuit (“Application-Specific Integrated Circuit”).

Furthermore, this device does not include an element coupled to the drain or to the source of the power transistor, or a power capture element of the power transistor. Hence, the characteristics and the response of the power transistor are not modified by this device. This property also has the advantage of reducing the cost of the proposed solution because, compared to the solutions of the prior art, it allows optimising the routing of the device and reducing the circuit area necessary for implantation thereof.

In this device, the short-circuit detection is based on the detection of an abnormal increase or decrease in the voltage V_{GS} of the power transistor, i.e. the detection of a depolarisation or an ohmic overpolarisation of the gate of the power transistor. The short-circuit detection carried out by the control and protection device allows detecting any short-circuit type.

Advantageously, the invention applies to the control and protection of a power transistor forming part of a power module or converter for the control of the motor of an aircraft.

The provided control and protection device makes the power electronics equipment in which power components or modules based on power transistors are used generally more reliable, safer and more available over a long time.

Advantageously, the control and protection device is used to protect a wide-bandgap-semiconductor-based power transistor (i.e. comprising an energy gap or a height of the bandgap Eg separating the last occupied states of the valence band and the first free states of the conduction band, greater than silicon) such as SiC or GaN. Advantageously, the controlled and protected power transistor corresponds to a silicon carbide MOSFET or a p-GaN HEMT for which an HSF or FUL-type short-circuit could be detected, but may correspond to another type of transistor like for example a JFET or an IGBT for which a FUL-type short-circuit could be detected.

The short-circuit detection circuit is coupled to the power transistor through resistors different from those via which the nominal switching circuit is coupled to the power transistor.

The nominal switching circuit may include at least:
a first push-pull circuit comprising a first output configured to be coupled to the gate of the power transistor through a first resistor, and a second output configured to be coupled to the gate of the power transistor through at least one second resistor;
a first voltage level conversion circuit comprising at least one first control input on which a nominal switching control signal is intended to be applied from the measurement and control circuit, a second control input on which a signal for setting in the high-impedance state the first and second outputs of the first push-pull circuit is intended to be applied from the measurement and control circuit, and configured to deliver, on outputs coupled to control inputs of the first push-pull circuit, signals for controlling the first push-pull circuit.

The first push-pull circuit may include at least one n-MOSFET transistor and one p-MOSFET transistor such that:
the gates of the n-MOSFET and p-MOSFET transistors form the control inputs of the first push-pull circuit;
a source electrode of the n-MOSFET transistor is configured to receive a first reference electrical potential;
a drain electrode of the n-MOSFET transistor forms the first output of the first push-pull circuit;
a source electrode of the p-MOSFET transistor is configured to receive a first power supply electrical potential;
a drain electrode of the p-MOSFET transistor forms the second output of the first push-pull circuit.

The short-circuit detection circuit of the power transistor may include at least:
a first switch comprising an output configured to be coupled to the gate of the power transistor through a third resistor;
a second voltage level conversion circuit comprising at least one control input on which a short-circuit detection control signal is intended to be applied from the measurement and control circuit, and configured to deliver, on an output coupled to a control input of the first switch, a signal for controlling the first switch;
a first comparator circuit configured to deliver, on an input of the measurement and control circuit, a signal representative of a difference between the value of the voltage V_{GS} of the power transistor and the value of the high reference voltage;
a second comparator circuit configured to deliver, on an input of the measurement and control circuit, a signal representative of a difference between the value of the voltage V_{GS} of the power transistor and the value of the low reference voltage.

The first switch may correspond to a p-MOSFET transistor which gate forms the control input of the first switch, a source electrode of which is configured to receive a second power supply electrical potential, and a drain electrode of which forms the output of the first switch.

The value of the third resistor may be higher than those of the first and second resistors by a multiplication factor greater than or equal to 100.

The protection circuit may include a second switch comprising an input configured to be coupled to the gate of the transistor power through a fourth resistor, and an output configured to be coupled to a reference electrical potential.

The second switch may correspond to an n-MOSFET transistor a source electrode of which forms the output of the second switch, a drain electrode of which forms the input of the second switch, and which gate is coupled to a control element configured to receive a control signal from the measurement and control circuit and to set in the conducting state the n-MOSFET transistor after a detection of a short-circuit of the power transistor.

The control and protection device may further include a circuit for monitoring a state-of-health of a gate oxide of the power transistor configured to:
control a slow switching of the power transistor in which the switching durations are longer than those of the nominal switching, and
measure the evolution of the voltage V_{GS} of the power transistor during a slow switching of the power transistor, and
calculate a duration of a so-called Miller plateau during the evolution of the measured voltage V_{GS},
and the measurement and control circuit may be configured to deliver control signals such that:
when the power transistor is controlled by the nominal switching circuit or by the short-circuit detection circuit, outputs of the monitoring circuit configured to be coupled to the gate of the power transistor are each set in a high-impedance state;
during a slow switching of the power transistor, the outputs of the nominal switching circuit and the short-circuit detection circuit and the input of the protection circuit are each set in a high-impedance state.

In this case, the control and protection device proposes extending the initial “gate-driver” function in order to add thereto a new function relating to monitoring of the “state-of-health” of the power transistor, in particular by detection of an abnormally high drift of its threshold voltage.

The monitoring circuit may include at least:
a second push-pull circuit comprising a first output configured to be coupled to the gate of the power transistor through a fifth resistor, a second output configured to be coupled to the gate of the power transistor through at least one sixth resistor;
a third voltage level conversion circuit comprising at least one first control input on which a monitoring control signal is intended to be applied from the measurement and control circuit, a second control input on which a signal for setting in the high-impedance state the first and second outputs of the second push-pull circuit is intended to be applied from the measurement and control circuit, and configured to deliver, on outputs coupled to control inputs of the second push-pull circuit, signals for controlling the second push-pull circuit;
a voltage measurement circuit including at least one sample-and-hold circuit an input of which is configured to be coupled to the gate of the power transistor.

The device may further include a first current non-return diode coupled in series with the second resistor between the second output of the first push-pull circuit and the gate of the power transistor, and a second current non-return diode coupled in series with the sixth resistor between the second output of the second push-pull circuit and the gate of the power transistor.

The second push-pull circuit may include at least one n-MOSFET transistor and one p-MOFET transistor such that:
the gates of the n-MOSFET and p-MOSFET transistors form the control inputs of the second push-pull circuit;
a source electrode of the n-MOSFET transistor is configured to receive a third reference electrical potential;
a drain electrode of the n-MOSFET transistor forms the first output of the second push-pull circuit;
a source electrode of the p-MOSFET transistor is configured to receive a third power supply electrical potential;
a drain electrode of the p-MOSFET transistor forms the second output of the second push-pull circuit.

The values of the fifth and sixth resistors may be higher than those of the first and second resistors by a multiplication factor higher than or equal to 10.

The control and protection device may further include a circuit for detecting a permanent leakage current through the gate of the power transistor configured to:
set the power transistor in the conducting or non-conducting state, and
measure the evolution of the current on the gate of the power transistor,
and wherein the measurement and control circuit is configured to deliver control signals such that:
when the power transistor is controlled by the nominal switching circuit or by the short-circuit detection circuit, or by the monitoring circuit when the control and protection device includes such a circuit, outputs of the permanent leakage current detection circuit are each set in a high-impedance state;
upon detection of a permanent leakage current, the outputs of the nominal switching circuit, the short-circuit detection circuit, and the monitoring circuit when the control and protection device includes such a monitoring circuit, and the input of the protection circuit are each set in a high-impedance state.

In this case, the control and protection device proposes extending the initial gate control circuit function to add thereto a new function relating to monitoring of the “state-of-health” of the power transistor, in particular by detection of “early” signs or precursory signs of ageing of the gate oxide (abnormally high permanent leakage residual current).

The permanent leakage current detection circuit may include at least:
a third push-pull circuit comprising a first output configured to be coupled to the gate of the power transistor through a seventh resistor, a second output configured to be coupled to the gate of the power transistor through an eighth resistor;
a fourth voltage level conversion circuit comprising at least one first control input on which a permanent leakage current detection control signal is intended to be applied from the measurement and control circuit, a second control input on which a signal for setting in the high-impedance state the first and second outputs of the third push-pull circuit is intended to be applied from the measurement and control circuit, and configured to deliver, on outputs coupled to control inputs of the third push-pull circuit, signals for controlling the third push-pull circuit;
a circuit for measuring the gate current of the power transistor, which inputs are coupled to the terminals of the seventh resistor and to the terminals of the eighth resistor.

The third push-pull circuit may include at least one n-MOSFET transistor and one p-MOFET transistor such that:
the gates of the n-MOSFET and p-MOSFET transistors form the control inputs of the third push-pull circuit;
a source electrode of the n-MOSFET transistor is configured to receive a fourth reference electrical potential;
a drain electrode of the n-MOSFET transistor forms the first output of the third push-pull circuit;
a source electrode of the p-MOSFET transistor is configured to receive a fourth power supply electrical potential;
a drain electrode of the p-MOSFET transistor forms the second output of the third push-pull circuit.

The values of the seventh and eighth resistors may be higher than those of the first and second resistors by a multiplication factor higher than or equal to 10⁵.

The invention also relates to a power converter or module comprising several power transistors and at least one control and protection device as described hereinabove and coupled to one of said power transistors.

The invention also relates to an aircraft comprising at least one power converter or module as described hereinabove.

Throughout the document, the terms “first”, “second”, “third”, etc. are used for the purpose of enumerating and distinguishing different elements, and not for the purpose of specifying an importance or a priority of these elements within the device.

### BRIEF DESCRIPTION OF THE DRAWINGS

The present invention will be better understood upon reading the description of embodiments given merely for indicative and in no way limiting purposes with reference to the appended drawings, wherein:

FIGS. 1A and 1B show an embodiment of a device for controlling and protecting a power transistor, object of the present invention, according to a particular embodiment;

FIG. 2 shows a variant of a short-circuit detection circuit forming part of a device for controlling and protecting a power transistor, object of the present invention;

FIG. 3 shows examples of control signals of the power transistor applied by the device for controlling and protecting a power transistor, object of the present invention, during switching and holding in the conducting state of the power transistor;

FIG. 4 shows gate voltages of a power transistor obtained upon a switching by the nominal switching circuit and by the gate oxide state monitoring circuit of the control and protection device, object of the present invention;

FIG. 5 shows a converter, object of the present invention, comprising several power transistors and at least one control and protection device, also object of the present invention, according to a particular embodiment;

FIG. 6 shows an example of an aircraft, object of the present invention, comprising at least one power converter or module also object of the present invention;

FIG. 7 schematically shows the apparition of a FUL-type short-circuit on an arm of a converter in which the gate of one of the power transistors is coupled to a control and protection device, object of the present invention;

FIG. 8 schematically shows the apparition of an HSF-type short-circuit on an arm of a converter in which the gate of one of the power transistors is coupled to a control and protection device, object of the present invention;

FIG. 9 schematically shows the evolution of the gate voltage of a power transistor during the apparition of a FUL or HSF type short-circuit.

Identical, similar or equivalent portions of the different figures described hereinafter bear the same reference numerals so as to facilitate passage from one figure to another.

The different portions shown in the figures are not necessarily plotted according to a uniform scale, in order to make the figures more legible.

The different possibilities (variants and embodiments) should be understood as not exclusive of one another and could be combined together.

### DETAILED DISCLOSURE OF PARTICULAR EMBODIMENTS

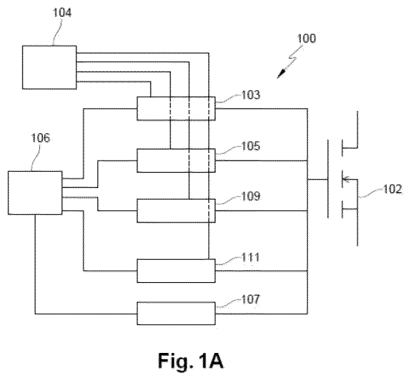

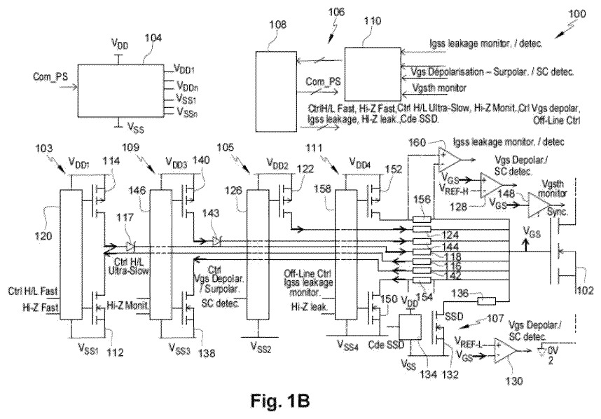

An embodiment of a device 100 for controlling and protecting a power transistor 102 according to a particular embodiment is described hereinbelow with reference to FIGS. 1A and 1B. The power transistor 102 corresponds to one of the power transistors of a power converter 200, for example as shown in FIG. 5, this converter corresponding for example to an inverter. As shown in FIG. 5, the gate of the power transistor 102 is coupled to the device 100. In the example of FIG. 5, one single device 100 coupled to the gate of one of the power transistors of the converter 200 is shown. In practice, each of the power transistors of the converter 200 advantageously includes its gate coupled to a control and protection device 100 similar to that one described herein.

The architecture of the device 100 consists of several circuits intended to control and protect the power transistor 102, operating in parallel in a modular and selective manner with respect to one another in order to carry out a dedicated function each. Each output of these circuits is dedicated to one single function that could be carried out independently and optimised, on demand, without exclusion with regards to the other functionalities executed by the other circuits of the device 100.

In FIGS. 1A and 1B, the electrical connections represented by dotted lines and passing through different circuits are not electrically connected to these circuits.

The device 100 includes a programmable power supply 104 intended to supply different power supply electrical potentials and different reference electrical potentials to the different circuits of the device 100. The programmable power supply 104 receives as input a power supply electrical potential V_{DD} and a reference electrical potential V_{SS}, as well as a control signal, so-called “Com_PS” in FIG. 1B. The programmable power supply 104 includes several outputs on which several pairs of supply and reference electrical potentials V_{DD1}, V_{SS1}, . . . , V_{DDn}, V_{SSn} (i.e. n pairs of power supply and reference electrical potentials in the example described herein, with n an integer greater than or equal to 2) are generated and delivered by the programmable power supply 104. In particular, the values of these electrical potentials may be parameterised by the control signal “Com_PS” received by the programmable power supply.

The device 100 also includes a measurement and control circuit 106 delivering, for example in the form of digital signals, the control signal “Com_PS” as well as other control signals intended to drive the circuits of the device 100 intended to control and protect the power transistor 102 (these other control signals will be detailed later on). In the example of FIG. 1B, these control signals are delivered by a digital control unit 108 forming part of the circuit 106.

In the example of FIG. 1B, the circuit 106 also includes a measurement processing unit 110 receiving at the input different measurement signals intended to be emitted by the circuits intended to control and protect the power transistor 102. These measurement signals will be detailed later on.

One of the circuits intended to control and protect the power transistor 102 corresponds to a nominal switching circuit 103 of the power transistor 102, configured to control a nominal switching of the power transistor 102 from a conducting state into a non-conducting state, hold the power transistor 102 in the non-conducting state, and control a nominal switching of the power transistor 102 from the non-conducting state into the conducting state. As will be described later on, holding the power transistor 102 in the conducting state will be ensured by another circuit of the device 100.

In the embodiment shown in FIG. 1B, the nominal switching circuit 103 includes a first push-pull circuit formed by two switches corresponding herein to an n-MOSFET 112 and a p-MOSFET 114.

A first reference electrical potential V_{SS1} delivered by the programmable power supply 104 is applied on the source of the n-MOSFET 112, and the drain of the n-MOSFET 112 is coupled to the gate of the power transistor 102 through a first resistor 116. A first power supply electrical potential V_{DD1} delivered by the programmable power supply 104 is applied on the source of the p-MOSFET 114, and the drain of the p-MOSFET 114 is coupled to the gate of the power transistor 102 through a gate current non-return diode 117 and a second resistor 118 coupled in series with the diode 117. The diode 117 allows avoiding the reverse conduction of the p-MOSFET 114 upon a FUL-type short-circuit, i.e. avoiding a reinjection of parasitic gate current by the substrate diode of the p-MOSFET 114 when a FUL-type fault appears with an increase in the potential on the gate of the power transistor 102.

Since the first push-pull circuit is intended to control the switching phases of the power transistor 102 while ensuring short switching times while minimising switching losses, the values of the first and second resistors 116, 118 are selected so as to minimise losses by switching or to meet, for example, a loss-EMC performance trade-off. For example, the values of the first and second resistors 116, 118 may be equal to 2 Ω and 10 Ω respectively.

In the embodiment shown in FIG. 1B, the nominal switching circuit 103 also includes a first voltage level conversion circuit 120 comprising a first control input on which a nominal switching control signal of the power transistor 102, denoted “Ctrl H/L Fast” in FIG. 1B, is intended to be applied from the circuit 106. This circuit 120 also includes outputs coupled to the gates of the MOSFETs 112 and 114 and on which control signals of the first push-pull circuit are intended to be delivered, according to the value of the control signal “Ctrl H/L Fast”. The circuit 120 also includes a second control input intended to receive a signal for setting in the high-impedance state the first and second outputs of the first push-pull circuit, denoted “Hi-Z Fast” in FIG. 1B, from the circuit 106. Such a high-impedance state of the first push-pull circuit corresponds to setting in a floating state the gate voltages of the MOSFETs 112, 114. It should be noted that this floating state does not prevent the possibility of a reverse conduction of the p-MOSFET 114, the diode 117 being coupled to the drain of the p-MOSFET 114 to avoid this reverse conduction.

The circuit 106 controls the nominal switching circuit 103 such that, when the power transistor 102 is intended to operate in a nominal switching mode, the nominal switching circuit 103 applies, through the second resistor 118, an electrical potential on the gate of the power transistor 102 controlling the switching (from the conducting state into the non-conducting state, or from the non-conducting state into the conducting state) of the power transistor 102, by setting in the conducting state the p-MOSFET transistor 114 and setting in the non-conducting state the n-MOSFET transistor 112. The value of the electrical potential applied on the gate of the power transistor 102 during a switching operation is for example equal to 20 V. When the power transistor 102 should be held in the non-conducting state, the nominal switching circuit 103 applies on the gate of the power transistor 102, through the first resistor 116, another electrical potential holding the power transistor 102 in the non-conducting state, in this case with setting in the non-conducting state the p-MOSFET transistor 114 and setting in the conducting state the n-MOSFET transistor 112. The value of the electrical potential applied on the gate of the power transistor 102 during a switching operation is for example comprised between −2 V and −5 V.

Another one of the circuits of the device 100 is configured to hold the power transistor 102 in the conducting state and detect an increase in the value of the voltage V_{GS} of the power transistor 102 above a value of a high reference voltage denoted V_{REF_H}, OR a drop in the value of the voltage V_{GS} below value of a low reference voltage value denoted V_{REF_L}, which are representative of a short-circuit of the power transistor 102. Hence, this other circuit, bearing the reference 105, forms a circuit for detecting a short-circuit of the power transistor 102.

In the embodiment of FIG. 1B, the short-circuit detection circuit 105 includes a switch 122 (corresponding to a p-MOSFET transistor in the example of FIG. 1B), so-called the first switch, comprising an output (corresponding to the drain of the p-MOSFET transistor) coupled to the gate of the power transistor 102 through a third resistor 124 which value is, in the embodiment described herein, equal to 2 kΩ. A second power supply electrical potential V_{DD2} delivered by the programmable power supply 104 is applied on the source of the p-MOSFET forming the first switch 122.

For example, the value of the third resistor 124 may be comprised between 1 kΩ and 5 kΩ. In general, the ratio of the value of the third resistor 124 to the value of the first resistor 116 and the ratio of the value of the third resistor 124 to the value of the second resistor 118 are higher than or equal to 100, contributing to the creation of a depolarisation of the gate voltage upon an HSF-type short-circuit or an overpolarisation by an ohmic effect with a suitable detection sensitivity upon a FUL-type short-circuit.

In the embodiment of FIG. 1B, the short-circuit detection circuit 105 also includes a second voltage level conversion circuit 126 comprising a control input on which a short-circuit detection control signal, denoted “Ctrl Vgs Depolar./Surpolar. SC detec.” and delivered at the output of the circuit 106, is intended to be applied, and configured to deliver, on an output coupled to a control input of the first switch 122 (the gate of the MOSFET in the example of FIG. 1B), at least one control signal of the first switch 122. Thanks to the signal “Ctrl Vgs Depolar./Surpolar. SC detec.”, the circuit 106 controls the short-circuit detection circuit 105 such that, when the power transistor 102 operates in a nominal switching mode, the short-circuit detection circuit 105 applies, through the third resistor 124, an electrical potential on the gate of the power transistor 102 controlling holding of the power transistor 102 in the conducting state by setting the first switch 122 in the conducting state. The value of the electrical potential applied on the gate of the power transistor 102 during holding of the power transistor 102 in the conducting state is, for example, comprised between 15 V and 20 V.

FIG. 3 shows examples of control signals applied by the nominal switching circuit 103 and the short-circuit detection circuit 105 on the gate of the power transistor 102. The reference 10 designates the control signal applied by the nominal switching circuit 103 during a switching phase of the power transistor 102 switching from the non-conducting state into the conducting state between the time points t1 and t2, and during a switching phase of the power transistor 102 switching from the conducting state into the non-conducting state between the time points t3 and t4. The reference 20 designates the control signal applied by the short-circuit detection circuit 105 and which has a positive value when the power transistor 102 is held in the conducting state.

In practice, short-circuit detection is effective only between the times t2 to t3. Indeed, between t1 and t2 and between t3 and t4, the nominal switching circuit 103 is activated in parallel with the voltage conversion circuit 126 of the short-circuit detection circuit 105. Given the lower values of the resistors 116, 118, the short-circuit detection circuit 105 does not use all its detection sensitivity. In other words, the time intervals t2-t1 and t4-t3 behave as masking intervals with regards to the detection of any short-circuit fault.

The short-circuit detection circuit 105 also includes a first comparator circuit 128 comprising, in the example of FIG. 1B, a non-inverting input coupled to the gate of the power transistor 102 and therefore receiving the gate potential G (or the voltage V_{GS}). The first comparator circuit 128 also includes an inverting input on which the high reference voltage V_{REF_H} is applied. This first comparator 128 delivers at the output a signal denoted “Vgs Surpolar./SC detec.” which value is positive when the value of the voltage V_{GS} exceeds the value of this high reference voltage V_{REF_H}, and which is sent at the input of the measurement processing unit 110 of the circuit 106.

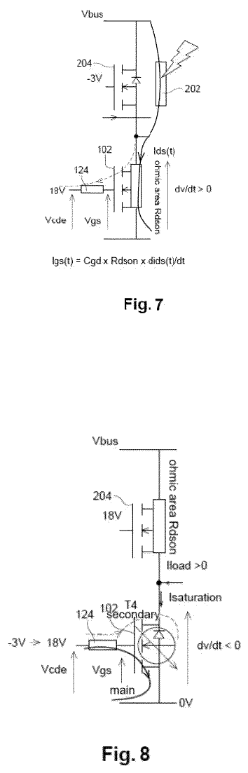

When the voltage V_{GS} exceeds this high reference voltage V_{REF_H}, this means that a FUL-type short-circuit is detected at the level of the power transistor 102. Indeed, in the case of such a FUL-type short-circuit, the variation dv/dt experienced by the transistor between its drain and source electrodes leads to a rise in the potential of its drain with respect to its source and to the apparition, via a drain-gate capacitive coupling internal to any power transistor, of a capacitive current of several hundreds of mA flowing from the gate of the power transistor 102 towards the third resistor 124 which abnormally raises the gate voltage (ohmic overpolarisation phenomenon) by one or more volt(s) above the nominal control voltage. The apparition of such a FUL-type short-circuit is schematised in FIG. 7 which shows the arm of the converter 200 to which the transistor 102 belongs and which is subjected to a load fault symbolised by a resistor 202. In the example of FIG. 7, the power transistor 102 is in the conducting state, with a control voltage Vcde of 18 V applied on its gate, and the other power transistor, designated by the reference 204, of the arm of the converter 200 is in the non-conducting state, with a control voltage equal to −3 V applied on its gate.

When the value of the third resistor 124 is much higher than that of the second resistor 118 (which is the case for the examples of previously-described values), the short-circuit detection circuit 105 may be left active (transistor 122 left in the conducting state) during the switching phases triggered by the nominal switching circuit 103.

The short-circuit detection circuit 105 also includes a second comparator circuit 130 comprising, in the example of FIG. 1B, a non-inverting input on which the low reference voltage V_{REF_L} is applied, and an inverting input coupled to the gate of the power transistor 102 and therefore receiving the gate potential V_{G} (or the voltage V_{GS}). This second comparator 130 outputs a signal denoted “Vgs Depolar./SC detec.” which value is positive when the voltage Vas becomes lower than the low reference voltage V_{REF_L}, and which is sent at the input of the measurement processing unit 110 of the circuit 106 (in FIG. 1B, the signals “Vgs Surpolar./SC detec.” and “Vgs Depolar./SC detec.” applied at the input of the unit 110 are represented as being applied on the same input of the unit 110 and designated by the expression “Vgs Depolarisation-Surpolar./SC detec.”.

When the voltage V_{GS} becomes lower than this low reference voltage V_{REF_L}, this means that a HSF type short-circuit is detected at the power transistor 102 because, in the case of such a HSF short-circuit, The apparition of a gate leakage current of thermal origin of several mA flowing from the third resistor 124 towards the gate of the power transistor 102 causes the gate voltage V_{GS} to drop abnormally by several hundred mV below the nominal control voltage (ohmic depolarisation phenomenon). The apparition of such an HSF-type short-circuit is schematised in FIG. 8 which shows the arm of the converter 200 to which the transistor 102 belongs which is in this case subjected to a control fault (setting in the conducting state the illustrated two power transistors).

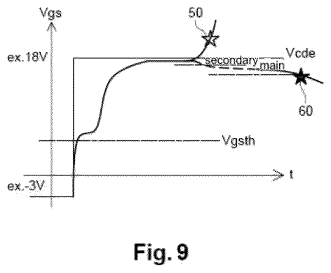

FIG. 9 schematically shows the evolution of the gate voltage V_{GS} of the power transistor 102 upon apparition of a short-circuit of the FUL type (the reference 50 designating the evolution of V_{GS} in this case) or HSF type (the reference 60 designating the evolution of V_{GS} in this case).

The device 100 also includes a protection circuit 107 configured to slowly discharge the gate of the power transistor 102 after a detection of a short-circuit of the power transistor 102. This protection circuit 107 is of the SSD, or “Soft Shut Down”, type. In the embodiment shown in FIG. 1B, this protection circuit 107 includes a MOSFET transistor 132 (of the n type in FIG. 1B) which gate is coupled to a control element 134 and which drain is coupled to the gate of the power transistor 102 through a fourth resistor 136. The control element 134 receives at the input a control signal denoted “Cde SSD” and sent from the circuit 106. This control signal “Cde SSD” triggers setting of the transistor 132 in the conducting state when a short-circuit of the power transistor 102 is detected by the short-circuit detection circuit 105, in order to ensure the safety blocking of the power transistor 102, with a slow discharge of its gate to avoid any hazardous overvoltage at its terminals. During this discharge of the gate, the other channels coupled to the gate of the power transistor 102 are deactivated (the gate driver circuit is set in the high-impedance state by control of the signal “Hi-Z Fast”, and the switch 122 is set in the non-conducting state).

In the embodiment shown in FIGS. 1A and 1B, the device 100 also includes a circuit 109 for monitoring a state-of-health of a gate oxide of the power transistor 102. This circuit 109 is configured to:
control a slow switching of the power transistor 102 in which the switching durations are much longer than those of the nominal switching mode, and
measure the evolution of the voltage V_{GS} of the power transistor 102 during such a slow switching, and
calculate a duration of the so-called Miller plateau in the evolution of the measured voltage V_{GS}.

To carry out these functions, this circuit 109 for monitoring the state-of-health of the gate oxide of the power transistor 102 comprises a second push-pull circuit formed for example like the previously-described first push-pull circuit, i.e. by an n-MOSFET 138 and a p-MOSFET 140. A third reference electrical potential V_{SS3} delivered by the programmable power supply 104 is applied on the source of the n-MOSFET 138, and the drain of the n-MOSFET 138 is coupled to the gate of the power transistor 102 through a fifth resistor 142 which value is, in the embodiment described herein, equal to 150 Ω. A third power supply electrical potential VDD3 delivered by the programmable power supply 104 is applied on the source of the p-MOSFET 140, and the drain of the p-MOSFET 140 is coupled to the gate of the power transistor 102 through a current non-return diode 143 and a sixth resistor 144 which value is, in the embodiment described herein, equal to 150 Ω. The diode 143 allows avoiding a parasitic gate current reinjection by the substrate diode of the p-MOSFET 140 when a FUL-type fault appears with an increase in the potential on the gate of the power transistor 102.

For example, the values of the fifth and sixth resistors 142, 144 may be comprised between 100 Ω and 500 Ω. In general, the ratio of the value of the fifth resistor 142 (or of the sixth resistor 144) to the value of the first resistor 116 and the ratio of the value of the fifth resistor 142 (or of the sixth resistor 144) to the value of the second resistor 118 are higher than or equal to 10.

In the embodiment shown in FIG. 1B, the circuit 109 for monitoring the state-of-health of the gate oxide of the power transistor 102 also comprises a third voltage level conversion circuit 146 comprising a first control input on which a slow switching control signal of the power transistor 102, denoted “Ctrl H/L Ultra-Slow”, is intended to be applied from the circuit 106. This circuit 146 includes outputs coupled to the gates of the MOSFETs 138, 140 and on which control voltages of the second push-pull circuit are intended to be delivered, according to the value of the control signal “Ctrl H/L Ultra-Slow”. The circuit 146 also includes a second control input intended to receive a signal for setting in the high-impedance state the outputs of the second push-pull circuit, denoted “Hi-Z Monit.”, from the circuit 106. Such a high-impedance state of the first push-pull circuit corresponds to setting in the floating state the gate voltages of the MOSFETs 138, 140. This high-impedance state is applied when the power transistor 102 operates in the nominal switching mode, or after a detection of a short-circuit of the power transistor by the short-circuit detection circuit 105 and during a discharge of the gate by the SSD protection circuit 107 that follows this detection.

The circuit 109 for monitoring the state-of-health of the gate oxide of the power transistor 102 also comprises a circuit 148 for measuring the voltage V_{GS}. This circuit 148 includes at least one sample-and-hold circuit (in FIG. 1B, the circuit 148 is schematised in the form of this sample-and-hold circuit) and includes an input on which the voltage V_{GS} is applied, and an output on which the completed measurement is delivered in the form of a digital signal so-called “Vgsth monitor.” which is sent at the input of the circuit 106. This circuit 148 could carry out other functions, such as a filtering function, an analog-to-digital conversion function, etc.

This circuit 109 for monitoring the state-of-health of the gate oxide of the power transistor 102 is activated occasionally, outside the nominal switching cycles of the power transistor 102. During the activation of this monitoring circuit, the other circuits of the device 100 are no longer active (setting in the high-impedance state the nominal switching circuit, setting in the non-conducting state the first and second switches 122, 132).

Because of the high values of the fifth and sixth resistors 142, 144, when this monitoring circuit is used, this results in a very low gate current on the power transistor 102 which results in a very long voltage Vds switching time. This long time is reflected by a so-called plateau voltage (or Miller plateau) on the voltage V_{GS}, with a stable and low-noise shape, and with a value close to the threshold voltage Vgth of the power transistor 102. This configuration is ideal for detecting and measuring the amplitude of this threshold in order to estimate the state-of-drift and the state-of-health of the gate oxide. For example, the detection of the start of the plateau voltage may be performed by an analog differentiator circuit integrated into the unit 110.

The curve 30 shown in FIG. 4 represents an example of the voltage Vgs of the power transistor 102 when a slow switching of this transistor, from the non-conducting state into the conducting state, is controlled by the circuit 109 for monitoring the state-of-health of the gate oxide, allowing determining its effective threshold voltage Vgth. This curve shows the apparition, during this slow switching, of the so-called plateau voltage between the time points t5 and t6 on the voltage V_{GS}, with a value close to the threshold voltage Vgth of the power transistor 102. For comparison, the curve 40 represents the voltage Vgs of the power transistor 102 when the power transistor 102 is switched from the non-conducting state into the conducting state by the nominal switching circuit 103 which applies a control voltage Vcde on the gate of the power transistor 102.

By regularly using this circuit 109 for monitoring the state-of-health of the gate oxide of the power transistor 102, it is possible to compare the obtained measurements of the plateau voltage, and thus follow the evolution of the drift of this threshold voltage over a long time, i.e. follow the ageing of the gate oxide of the power transistor 102, allowing deciding on the continuation or stoppage of use thereof before this transistor is excessively degraded.

This slow switching carried out by the circuit 109 for monitoring the state-of-health of the gate oxide of the power transistor 102 cannot be used at a high chopping frequency because of excessive losses that would be generated. Hence, this monitoring circuit 109 carries out this slow switching occasionally, preferably at a low charging current level, so that the measured Miller plateau voltage coincides with the threshold voltage Vgsth of the power transistor 102.

According to a variant of the device 100, the push-pull circuit formed by the switches 138, 140 could be replaced by one single switch, for example a p-MOSFET, coupled to the diode 143 and to the resistor 144. In this case, the measurement of the voltage V_{GS} is carried out by the circuit 148 only by switching the power transistor 102 from the non-conducting state into the conducting state.

In the particular embodiment described herein, the device 100 also includes another channel formed by a circuit 111 for detecting a permanent leakage current through the gate of the power transistor 102. This detection is relevant to prevent early ageing of the gate oxide of the power transistor 102.

The circuit 111 for detecting a permanent leakage current through the gate of the power transistor 102 is configured to:
set the power transistor 102 in the conducting or non-conducting state, and
measure the evolution of the current on the gate of the power transistor.

To carry out this detection, this circuit 111 for detecting a permanent leakage current through the gate of the power transistor 102 comprises a third push-pull circuit formed, for example, like the previously-described first and second push-pull circuits, i.e. by a n-MOSFET 150 and a p-MOSFET 152. A fourth reference electrical potential Vss4 delivered by the programmable power supply 104 is applied on the source of the n-MOSFET 150, and the drain of the n-MOSFET 150 is coupled to the gate of the power transistor 102 through a seventh resistor 152 which value is, in the embodiment described herein, equal to 1.2 MΩ. A fourth power supply electrical potential V_{SS4} delivered by the programmable power supply 104 is applied on the source of the p-MOSFET 152, and the drain of the p-MOSFET 152 is coupled to the gate of the power transistor 102 through an eighth resistor 156 which value is, in the embodiment described herein, equal to 1 MΩ. Given the very high value of the eighth resistor 156 with respect to those of the other resistors coupled to the gate of the power transistor 102, it is not necessary to couple a current non-return diode in series with this eighth resistor 156.

For example, the values of the seventh and eighth resistors 154, 156 may be comprised between 10 kΩ and 1 MΩ. In general, the ratio of the value of the seventh resistor 154 (or of the eighth resistor 156) to the value of the first resistor 116 and the ratio of the value of the seventh resistor 154 (or of the eighth resistor 156) to the value of the second resistor 118 are higher than or equal to 10⁴.

In the embodiment shown in FIG. 1B, the circuit 111 for detecting a permanent leakage current through the gate of the power transistor 102 also comprises a fourth voltage level conversion circuit 158 comprising a first control input on which a permanent leakage current detection control signal, so-called

“Off-Line Ctrl Igss leakage monitor”. is intended to be applied from the circuit 106. This circuit 158 includes outputs coupled to the gates of the MOSFETs 150, 152 and on which control voltages of the third push-pull circuit are intended to be delivered, according to the value of the control signal “Off-Line Ctrl Igss leakage monitor”. The circuit 158 also includes a second control input intended to receive a signal for setting in the high-impedance state the outputs of the third push-pull circuit, so-called “Hi-Z leak”, from the circuit 106. Such a high-impedance state of the third push-pull circuit corresponds to setting in the floating state the gate voltages of the MOSFETs 150 and 152. This high-impedance state is applied when the power transistor 102 operates in the nominal or slow switching mode, or after detection of a short-circuit of the power transistor by the short-circuit detection circuit 105 and during the discharge of the gate that follows this detection.

The circuit 111 for detecting a permanent leakage current through the gate of the power transistor 102 also comprises a circuit 160 for high-accuracy measurement of the gate current of the power transistor 102, comprising inputs coupled to the terminals of the seventh resistor 154 and the eighth resistor 156. In FIG. 1B, this circuit 160 is symbolised by a differential amplifier which inputs are coupled to the terminals of the eighth resistor 156. The measurement signal delivered at the output of the circuit 160 is applied at the input of the unit 110 and is denoted, in FIG. 1B, “Igss leakage monitor./detec.”.

The circuit 111 for detecting a permanent leakage current through the gate of the power transistor 102 is used when the power transistor 102 is in the conducting or non-conducting state (preferably in the non-conducting state, for several minutes, or several hours), and carrying out the measurement respectively at the terminals of the eighth resistor 156 or of the seventh resistor 154. When this detection is carried out with the power transistor 102 in the non-conducting state, the detection is non-intrusive but the gate voltage applied thereto is considerably reduced compared to the conducting state. In all cases of use, a very high resistor (seventh or eighth resistor) is inserted between the output channel and the gate of the transistor 102 in order to be able to detect a very low permanent leakage current through the gate of the power transistor 102 (in the range of about one hundred nA). During this detection, all of the other channels of the device 100 are uncoupled from the power transistor 102, i.e. the circuits 120 and 146 are set in the high-impedance state, and the switches 122 and 132 are in the non-conducting state.

According to a variant of the device 100, the push-pull circuit formed by the switches 150, 152 could be replaced by one single switch, for example, a p-MOSFET coupled to resistor 156 or an n-MOSFET coupled to resistor 154. In this case, the permanent leakage current detection is carried out only when the power transistor 102 is in the conducting state (in the case of a p-MOSFET coupled to the resistor 156) or in the non-conducting state (in the case of an n-MOSFET coupled to resistor 154).

The previously-described different elements of the device 100 form channels configured to operate in parallel, with resistors switched by these channels, with differentiated values, so as to act selectively to produce the desired effect in terms of control of the power transistor 102, of monitoring of the state- of-health of the power transistor 102 or of protection thereof. All these resistors are coupled to the gate of the power transistor 102.

In the above-described embodiment, the switches and the push-pull circuits are made using MOSFET transistors which have the advantage of enabling a good integration (in terms of size) of the device 100 while limiting losses. Nevertheless, the use of other technologies to make these switches and/or the push-pull circuits is possible, like, for example, the use of bipolar transistors.

For example, the device 100 may be made either in the form of a monolithic fully-integrated circuit (for example an ASIC), or in the form of a set of discrete components on a printed circuit board, or in a hybrid form mixing the previous embodiments in proportions defined on a case-by-case basis (monolithic integrated circuits and discrete components).

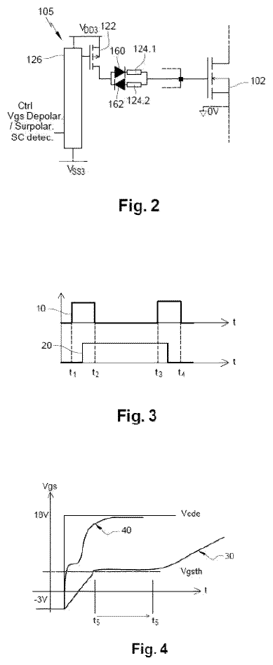

In the previously-described embodiment, the switch 122 of the short-circuit detection circuit 105 is coupled to the gate of the power transistor 102 via one single third resistor 124 which is used to detect both HSF-type and FUL-type short-circuits. Alternatively, it is possible to differentiate the detection of these two types of short-circuit by using, instead of the single third resistor 124, two different resistors coupled in parallel. FIG. 2 shows the short-circuit detection circuit 105 according to this variant. In this variant, this circuit 105 includes a resistor 124.1 coupled in series to a first diode 160 enabling the current to flow from the switch 122 up to the gate of the power transistor 102 and therefore enabling the detection of an HSF-type short-circuit. In parallel with this resistor 124.1 and this first diode 160, the short-circuit detection circuit 105 also includes another resistor 124.2 coupled in series to a second diode 162 enabling the current to flow from the gate of the power transistor 102 up to the switch 122 and therefore enabling the detection of a FUL-type short-circuit. Advantageously, this configuration is used to select different resistance values 124.1, 124.2 and thus enable a differentiated choice for the detection of the two types of short-circuits.

In the previously-described embodiment, the device 100 includes one single nominal switching circuit 103. In one variant, the device 100 may include several nominal switching circuits 103 coupled in parallel to the gate of the power transistor 102. For example, each of these nominal switching circuits 103 includes a push-pull circuit wherein the gates of the MOSFETS (for example similar to the MOSFETs 112, 114) are coupled to a voltage level conversion circuit (for example similar to the circuit 120) and wherein the outputs are each coupled to the gate of the power transistor 102 via a resistor which value is generally lower than 100 Ω. These resistors are distinct for each of the nominal switching circuits 103, i.e. each nominal switching circuit 103 is associated with a pair of resistors that is specific thereto. Such a configuration of the device 100 comprising several nominal switching circuits 103 allows best adapting the losses by switching/EMC trade-off according to the variability of the operating point in charging current, the operating voltage and the temperature of the power transistor 102.

In this variant, the power supply and reference electrical potentials applied on each of the nominal switching circuits 103 may be different, which allows acting on the conditioning of the threshold voltage Vgsth of the power transistor 102 in the conducting or non-conducting state. Indeed, a power supply electrical potential with a high value will tend to compensate for a negative drift of the threshold voltage Vgsth, whereas a power supply electrical potential with a lower value will tend to compensate for a positive drift of this threshold voltage Vgsth. Thus, the alternating or modulated use of these different power supply and reference electrical potentials allows stabilising the measured threshold voltage Vgsth in order to keep it within a desired range of values.

In the previously-described embodiment, the diodes 117 and 143 used to avoid a parasitic gate current reinjection advantageously correspond to zener or transil diodes, which allows protecting the gate of the power transistor 102 from an overvoltage that might appear during a FUL-type short-circuit, in case of a delay in blocking the power transistor 102. Alternatively, it is possible to use other types of elements for protecting the gate of the transistor 102, the diodes 117 and 143 could in this case consist of standard power diodes.

As a variant of the previously-described embodiment, it is possible that the device 100 does not include all of the previously-described circuits. Thus, it is possible that the device 100 does not include the circuit 109 for monitoring the gate oxide state-of-health and/or the permanent leakage current detection circuit 111.

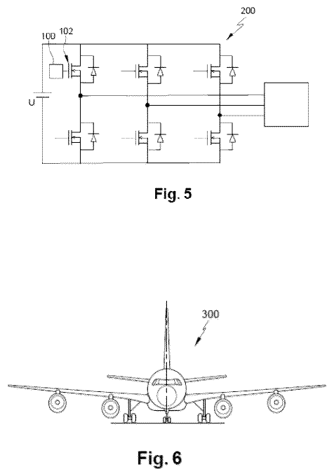

Advantageously, the device 100 is used to control and protect the power transistors of a power converter 200 used within an aircraft 300, an example of which is shown in FIG. 6.

1. A device for controlling and protecting a power transistor, comprising at least:
a nominal switching circuit of the power transistor, configured to control a nominal switching of the power transistor from a conducting state into a non-conducting state, hold the power transistor in the non-conducting state, and a nominal switching of the power transistor from the non-conducting state into the conducting state;
a short-circuit detection circuit, configured to hold the power transistor in the conducting state and detect an increase in the value of the voltage V_{GS} of the power transistor above a value of a high reference voltage, or a drop in the value of the voltage V_{GS} below a value of a low reference voltage, which are representative of a short-circuit of the power transistor;
a protection circuit, configured to discharge the gate of the power transistor after detection of a short-circuit of the power transistor;
a measurement and control circuit configured to deliver control signals at the input of the nominal switching circuit, the short-circuit detection circuit and the protection circuit such that:
in the absence of a detected short-circuit, an input of the protection circuit coupled to the gate of the power transistor is set in a high-impedance state;
in the presence of a detected short-circuit, outputs of the nominal switching circuit and the short-circuit detection circuit coupled to the gate of the power transistor are each set in a high-impedance state.

2. The device according to claim 1, wherein the nominal switching circuit includes at least:
a first push-pull circuit comprising a first output configured to be coupled to the gate of the power transistor through a first resistor, and a second output configured to be coupled to the gate of the power transistor through at least one second resistor;
a first voltage level conversion circuit comprising at least one first control input on which a nominal switching control signal is intended to be applied from the measurement and control circuit, a second control input on which a signal for setting in the high-impedance state the first and second outputs of the first push-pull circuit is intended to be applied from the measurement and control circuit, and configured to deliver, on outputs coupled to control inputs of the first push-pull circuit, signals for controlling the first push-pull circuit.

3. The device according to claim 1, wherein the short-circuit detection circuit includes at least:
a first switch comprising an output configured to be coupled to the gate of the power transistor through a third resistor;
a second voltage level conversion circuit comprising at least one control input on which a short-circuit detection control signal is intended to be applied from the measurement and control circuit, and configured to deliver, on an output coupled to a control input of the first switch, a signal for controlling the first switch;
a first comparator circuit configured to deliver, on an input of the measurement and control circuit, a signal representative of a difference between the value of the voltage V_{GS} of the power transistor and the value of the high reference voltage;
a second comparator circuit configured to deliver, on an input of the measurement and control circuit, a signal representative of a difference between the value of the voltage V_{GS} of the power transistor and the value of the low reference voltage.

4. The device according to claim 1, wherein the protection circuit includes a second switch comprising an input configured to be coupled to the gate of the transistor power through a fourth resistor, and an output configured to be coupled to a reference electrical potential.

5. The device according to claim 1, further including a circuit for monitoring a state-of-health of a gate oxide of the power transistor configured to:
control a slow switching of the power transistor in which the switching durations are longer than those of the nominal switching, and
measure the evolution of the voltage V_{GS} of the power transistor during a slow switching of the power transistor, and
calculate a duration of a so-called Miller plateau during the evolution of the measured voltage V_{GS},
and wherein the measurement and control circuit is configured to deliver control signals such that:
when the power transistor is controlled by the nominal switching circuit or by the short-circuit detection circuit, outputs of the monitoring circuit configured to be coupled to the gate of the power transistor are each set in a high-impedance state;
during a slow switching of the power transistor, the outputs of the nominal switching circuit and the short-circuit detection circuit and the input of the protection circuit are each set in a high-impedance state.

6. The device according to claim 5, wherein the monitoring circuit includes at least:
a second push-pull circuit comprising a first output configured to be coupled to the gate of the power transistor through a fifth resistor, a second output configured to be coupled to the gate of the power transistor through at least one sixth resistor;
a third voltage level conversion circuit comprising at least one first control input on which a monitoring control signal is intended to be applied from the measurement and control circuit, a second control input on which a signal for setting in the high-impedance state the first and second outputs of the second push-pull circuit is intended to be applied from the measurement and control circuit, and configured to deliver, on outputs coupled to control inputs of the second push-pull circuit, signals for controlling the second push-pull circuit;
a voltage measurement circuit including at least one sample-and-hold circuit an input of which is configured to be coupled to the gate of the power transistor.

7. The device according to claim 2, further including a first current non-return diode coupled in series with the second resistor between the second output of the first push-pull circuit and the gate of the power transistor, and a second current non-return diode coupled in series with the sixth resistor between the second output of the second push-pull circuit and the gate of the power transistor.

8. The device according to claim 1, further including a circuit for detecting a permanent leakage current through the gate of the power transistor configured to:
set the power transistor in the conducting or non-conducting state, and
measure the evolution of the current on the gate of the power transistor,
and wherein the measurement and control circuit is configured to deliver control signals such that:
when the power transistor is controlled by the nominal switching circuit or by the short-circuit detection circuit, or by the monitoring circuit when the control and protection device includes such a circuit, outputs of the permanent leakage current detection circuit are each set in a high-impedance state;
upon detection of a permanent leakage current, the outputs of the nominal switching circuit, the short-circuit detection circuit, and the monitoring circuit when the control and protection device includes such a monitoring circuit, and the input of the protection circuit are each set in a high-impedance state.

9. The device according to claim 8, wherein the permanent leakage current detection circuit includes at least:
a third push-pull circuit comprising a first output configured to be coupled to the gate of the power transistor through a seventh resistor, a second output configured to be coupled to the gate of the power transistor through an eighth resistor;
a fourth voltage level conversion circuit comprising at least one first control input on which a permanent leakage current detection control signal is intended to be applied from the measurement and control circuit, a second control input on which a signal for setting in the high-impedance state the first and second outputs of the third push-pull circuit is intended to be applied from the measurement and control circuit, and configured to deliver, on outputs coupled to control inputs of the third push-pull circuit, signals for controlling the third push-pull circuit;
a circuit for measuring the gate current of the power transistor, which inputs are coupled to the terminals of the seventh resistor and to the terminals of the eighth resistor.

10. A power converter or module comprising several power transistors and at least one control and the device according to claim 1 coupled to one of said power transistors.

11. An aircraft comprising at least one power converter or module according to claim 10.
